(19) United States
(12) Patent Application Publication
(10) Pub. No.: US 2003/0102485 A1
(43) Pub. Date: Jun. 5, 2003

(54) Variable trigger voltage silicon controlled rectifier

(75) Inventors: Shui-Hung Chen, Hsin-Chu (TW); Jian-Hsing Lee, Hsin-Chu (TW); Jiaw-Ren Shih, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/006,269

(22) Filed: Dec. 4, 2001

(51) Int. Cl. H01L 29/74

(52) U.S. Cl. 257/119

(57) ABSTRACT

A silicon controlled rectifier includes a pair of complementary bipolar transistors. At least one of the pair of transistors exhibits a reach-through effect that occurs prior to the avalanche junction voltage breakdown.

### TECHNICAL FIELD

The present invention is generally related to devices for protecting circuits against the effects of transient electrical discharges.

### BACKGROUND OF THE INVENTION

It is well known that high-voltage electrical transients when discharged through a silicon device can cause irreparable harm to the device. Transients can occur at anytime in a product's cycles of manufacturing, testing, assembly, field handling and service.

Many electronic devices, such as disk drive components, are acutely susceptible to damage at voltages as low as 10 volts. Many sources of such transients exist, among them are ancillary circuitry inductive effects, poor power quality control, inadequate circuit isolation, circuit board design, lightning strikes and electrostatic discharges (ESD).

The detrimental effect of many of these transients can be minimized through appropriate measures designed to minimize the likelihood of and prevent the occurrence of certain transients in the first place. For example, a well designed circuit board layout will reduce loop areas, have substantial ground planes and locate sensitive electronic components away from potential transient sources (transformers, coils, etc.). As another example, production handling methods can greatly reduce the risk of triboelectric charge build-up and discharge through the device.

However, if not impossible it is extremely improbable that all detrimental transient events can ever be eliminated, particularly with respect to ESD. ESD is a particularly nagging issue requiring constant vigilance against its direct effects on the integrated circuit product at many steps in its handling. It is quite possible that an ESD discharge event during handling might not cause a direct catastrophic failure of a component. Rather, a latent defect may be caused which might not be detected during testing or burn-in but which might later manifest itself in the field.

Complimentary metal oxide semiconductor (CMOS) transistor circuits are very susceptible to ESD damage. The combination of very thin gate oxides and short channel lengths makes ESD a particularly acute problem in high density CMOS applications.

Widely used techniques to address ESD events in CMOS applications includes chip-level designs intended to control the dissipation of charge in the event of such transients. Critical points on an integrated circuit, generally coupled at the contact pads thereof, may be protected by suppression devices such as voltage-clamping diodes or silicon controlled rectifiers (SCR). Due to its high current handling capability, very low turn-on impedance, low power dissipation, and large physical volume for heat dissipation, lateral SCR devices have been recognized in the art as one of the most effective elements in CMOS on-chip ESD protection circuits.

To perform ESD protection, the trigger voltage of an ESD protection circuit must be less than the voltage that can damage the input buffer or output driver. However, SCR trigger voltages, that is voltages across the anode and cathode of the SCR, are generally too high to protect adequately against ESD without modification. Trigger voltage for an unmodified lateral SCR in sub-micron CMOS devices is in the range of 30 to 50 volts. The typical thickness of gate oxide layers in CMOS fabrication processes employing a resolution of 0.6 to 0.8 microns is about 150-200 angstrom. Considering a dielectric breakdown strength of 10 MV/cm for typical SiO2 material, the gate oxide layers in these sub-micron CMOS devices would be destroyed by a voltage of 15 to 20 volts. Therefore, a lateral SCR with a trigger voltage in the range of 30 to 50 volts must be fitted with other protection components so that it can provide protection for gate oxide layers in the sub-micron CMOS IC devices.

Referring to FIGS. 1A and 1B, the schematic device structure and device I-V characteristics are shown, respectively, for an unmodified lateral SCR device that provides input ESD protection. The trigger voltage of the LSCR device in the CMOS technology is about approximately equal to approximately 50V. The trigger voltage is measured across the SCR device terminal (pad to reference voltage, in this example ground). The trigger voltage is, in an unmodified SCR device, the voltage at which conduction across the avalanche junction occurs (avalanche junction breakdown voltage). The avalanche junction in the presently described FIG. 1A is labeled by the numeral 7.

Referring to FIGS. 2A and 2B, the schematic device structure and device I-V characteristics are shown, respectively, for a modified lateral SCR device which provides input ESD protection. The trigger voltage of the SCR in the CMOS technology is about approximately equal to approximately 25V.

Referring to FIGS. 3A, 3B and 3C, the schematic device structure, device I-V characteristics and circuit diagram are shown, respectively, for a low-voltage-trigger, NMOS-modified lateral SCR device which provides input ESD protection. The trigger voltage of the SCR device in CMOS technology is about approximately equal to approximately 10V.

While each of FIGS. 2A and 3A represent advances in lowering the trigger voltage of the unmodified SCR structure shown in FIG. 1A, a description of the NMOS-modified SCR is given below for a general understanding of the basic and modified SCR device structures and integration thereof with CMOS structure.

FIG. 3A is a cross-sectional view of a typical prior art CMOS structure protected from ESD pulses by a lateral SCR and NMOS transistor. Shown is a semiconductor wafer 10 with CMOS devices, with pair of parasitic, complementary bipolar transistors forming an SCR, and an additional NMOS device for lowering the trigger voltage of the SCR. In a P-substrate 11 an N-well 12 is formed, and a p-channel transistor with a P+ source 14 and a P+ drain (not shown) is created. An N+ contact region 13 is formed in the lightly doped N-well and together with P+ source 14 connected to pad 19. In lightly doped P-substrate 11 an n-channel transistor with an N+ drain 15, an N+ source 16, and a gate 17 is created. The N+ drain 15 straddles P-substrate 11 and N-well 12. A P+ contact region 18, formed in P-substrate 11, is connected together with N+ source 16 to a reference voltage VSS (ground) 20.

The steps that produce the above CMOS structure also create parasitic bipolar pnp transistor 21 between P+ source 14 (emitter), N-well 12 (base), and P-substrate 11 (collector), and parasitic bipolar npn transistor 22 between N+ source 16 (emitter), P-substrate 11 (base), and N-well 12 (collector). Together, the npn and pnp transistors make up a pair of complementary bipolar transistors, that is to say one npn type transistor and one pnp type transistor. The base of transistor 21 is connected via N-well resistor 23 to N+ contact region 13, and the base of transistor 22 is connected via P-substrate resistor 24 to P+ contact region 18. The base of one transistor is connected to the collector of the other transistor. The interface between the N-well and P-substrate is referred to as the avalanche junction. Resistors 23 and 24 are equivalent resistors for the intrinsic resistance of the N-well and P-substrate material. FIG. 3C is the equivalent circuit of FIG. 3A showing the interconnection of transistor 21 and 22 forming an SCR. NMOS transistor Q1 is shunted across npn transistor 22 providing the trigger for the SCR. ESD voltage pulses are shunted from pad 19 via transistors 21 and 22 to reference voltage VSS (ground) 20.

These advances have reduced the effective SCR trigger voltages by the use of NMOS and PMOS devices as described. However, NMOS and PMOS devices so incorporated will have substantial device size in accordance with the source, drain and gate regions inherent in such devices. This issue is particularly acute when considering that more and more devices having greater numbers of pin-outs continue to be developed. And, NMOS and PMOS devices so incorporated provide a relatively inflexible trigger voltage adaptations. Furthermore, NMOS and PMOS modified SCR devices have current dissipation limits related to the NMOS and PMOS devices which are substantially less that the current dissipation capacity of the lateral SCR.

### SUMMARY OF THE INVENTION

Therefore, it is one object of the present invention to protect integrated circuits against transient voltage events. It is a further object of the present invention to provide such protection in-situ or on-chip.

It is a further object of the present invention to provide such protection in accordance with CMOS compatible manufacturability.

It is yet a further of the present invention to provide such protection in a manner that allows for variation of the trigger threshold voltage level at which such protection is effective.

It is yet a further object of the present invention to provide such protection in a space-efficient, CMOS manufacturing compatible design.

It is yet a further object of the present invention to provide such protection adaptable against both positive and negative phase voltage transients.

It is yet a further object of the present invention to provide such protection in a device having higher burn-out current tolerance than prior art NMOS and PMOS auxiliary triggering devices.

In accordance with these and other objects and advantages, the present invention comprises an on-chip SCR ESD protection device that is characterized by a low trigger threshold voltage effected without the integration of an auxiliary triggering device. The structure is a SCR device wherein the triggering mechanism is a reach-through assisted conduction. Reach-through assisted conduction as the term may be used herein is understood to mean SCR triggering caused by, attributed or due to, collector voltage reaching through the base to the emitter in at least one of the pair of bipolar transistors making up the SCR device. Reach-through is understood to be effectuated by expansion of the collector-junction depletion region width across the base an may be influenced by various combinations of device geometries and dimensions, doping concentrations and gradients, and substrate and dopant selection.

In accordance with one embodiment of the present invention, reach-through assisted conduction is effected by laying out the lateral SCR in an N-well fabrication process such that the base width interposed between the heavily doped P+ region and the P-substrate of the pnp bipolar transistor is sufficiently narrow that reach-through is effected therethrough.

In accordance with another embodiment of the present invention, reach-through assisted conduction is effected by laying out the lateral SCR in an P-well fabrication process such that the base width interposed between the heavily doped N+ region and the N-substrate of the npn bipolar transistor is sufficiently narrow that reach-through is effected therethrough.

In accordance with yet another embodiment of the present invention, reach-through assisted conduction is effected by laying out the lateral SCR in an N-well fabrication process such that the base width interposed between the heavily doped N+ region and the N-well of the npn bipolar transistor is sufficiently narrow that reach-through is effected therethrough.

In accordance with yet another embodiment of the present invention, reach-through assisted conduction is effected by laying out the lateral SCR in an P-well fabrication process such that the base width interposed between the heavily doped P+ region and the P-well of the pnp bipolar transistor is sufficiently narrow that reach-through is effected therethrough.

The various embodiments preferably establish base width laterally within the device layout. However, alternatively, base width may be established at the bottom of the well below the heavily doped region and the substrate in either of the N-well or P-well fabrication embodiments. Additionally, alternative embodiments may be effected in layered devices.

### BRIEF DESCRIPTION OF THE DRAWINGS

The present invention will now be described, by way of example, with reference to the accompanying drawings, in which:

FIGS. 1A and 1B show the schematic device structure and, device I-V characteristics, respectively, for a lateral SCR device used as an input ESD protection circuit;

FIGS. 2A and 2B show the schematic device structure and device I-V characteristics, respectively, for a modified lateral SCR device used as an input ESD protection circuit;

FIGS. 3A, 3B and 3C show the schematic device structure, device I-V characteristics, and circuit diagram for the low-voltage-trigger lateral SCR device used as an input ESD protection circuit;

FIG. 4 is a sectional schematic diagram of an exemplary embodiment of an ESD protection device made in accordance with N-well fabrication techniques;

FIG. 5 is a sectional schematic diagram of an exemplary embodiment of an ESD protection device made in accordance with N-well fabrication techniques;

FIG. 6 is an exemplary layout view of an ESD protection device in accordance with the present invention; FIG. 7 is an alternative exemplary layout view of an ESD protection device in accordance with the present invention;

FIG. 8 is a graph showing exemplary trigger voltages of devices according to the present invention;

FIG. 9 is a graph comparing relative device burn-out of an nMOS auxiliary triggering device and an SCR according to the present invention;

FIG. 10 is a sectional schematic diagram of an exemplary embodiment of an ESD protection device made in accordance with P-well fabrication techniques;

FIG. 11 is a sectional schematic diagram of an exemplary embodiment of an ESD protection device made in accordance with P-well fabrication techniques; and

FIG. 12 is a sectional schematic diagram of an exemplary embodiment of an ESD protection device made in accordance with layered fabrication techniques.

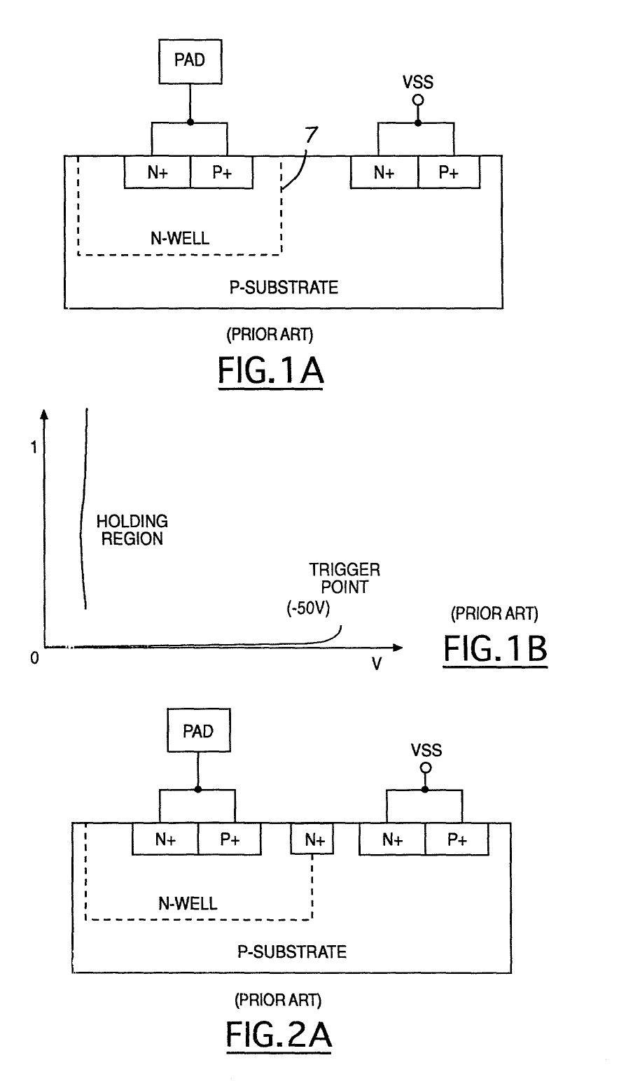

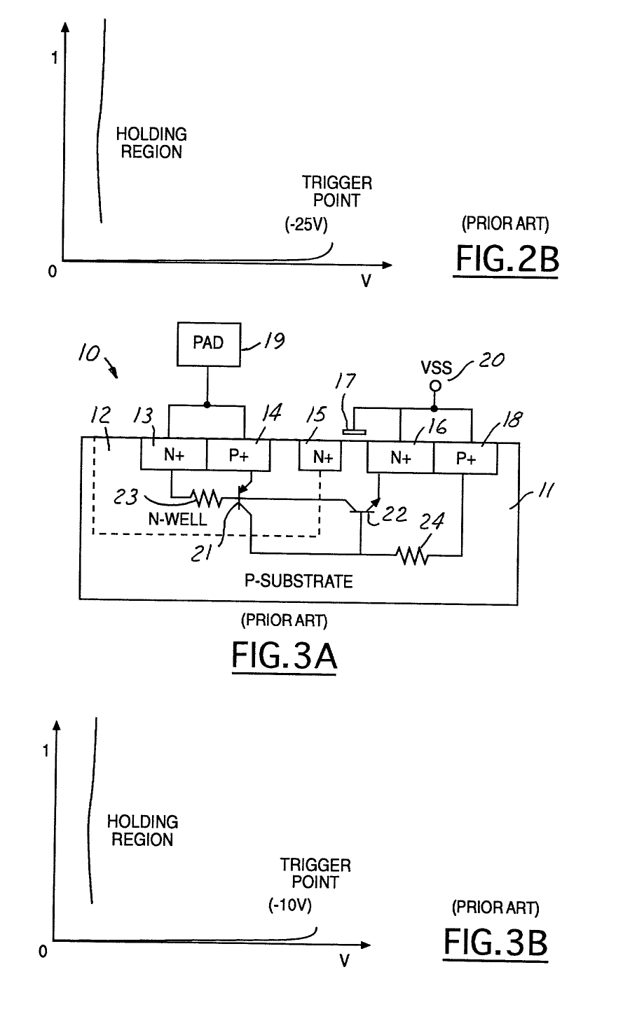

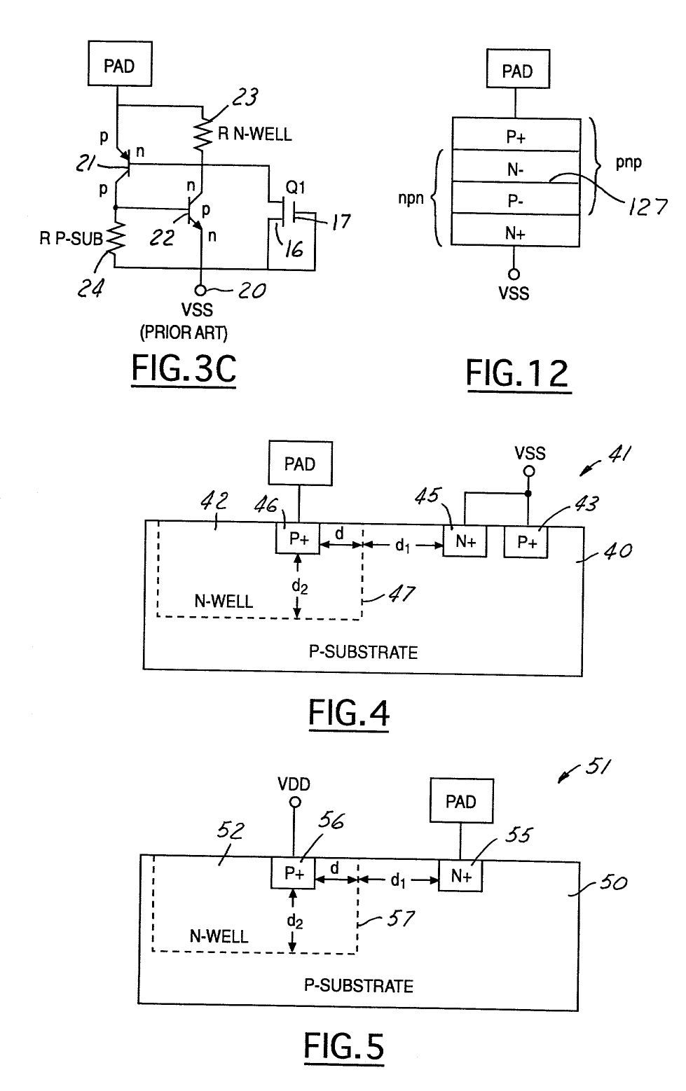

### DESCRIPTION OF THE PREFERRED EMBODIMENT

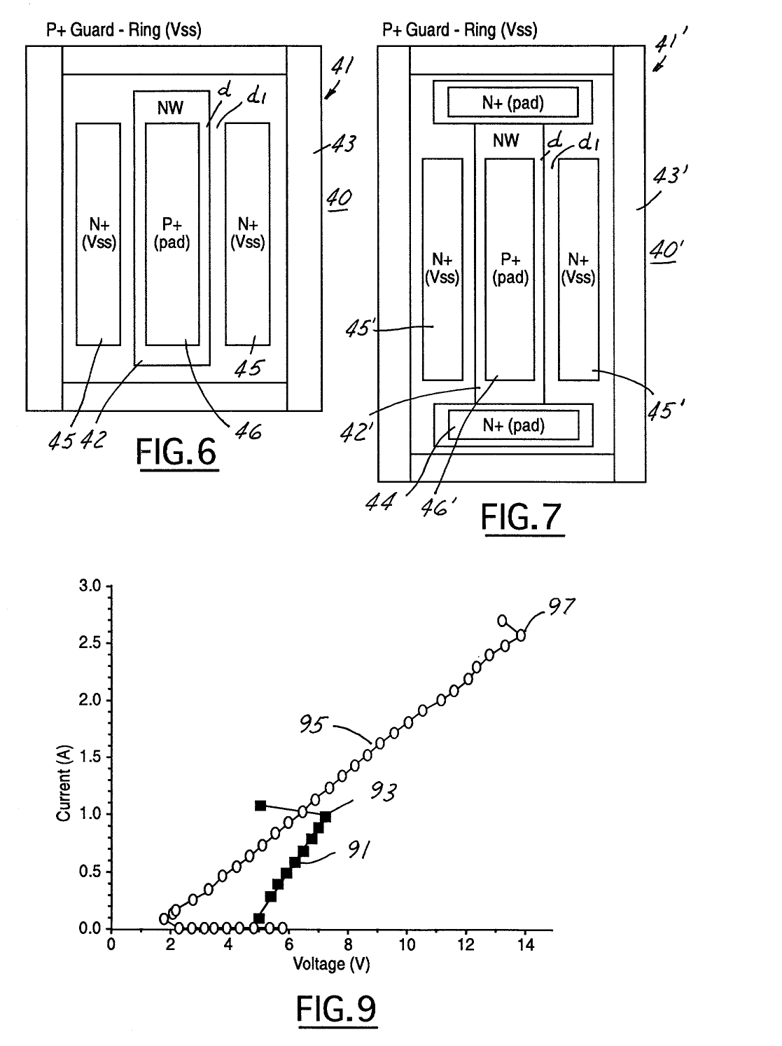

According to the present invention, FIG. 4 illustrates one embodiment of a SCR device in accordance with the present invention. The device of FIG. 4 is shown configured to pad and reference voltage VSS (ground) predominantly for positive transient (at pad) protection (though through modifications detailed with respect to the layout of FIG. 7 may be suitable for negative transient protection by a functionally different mechanism). The exemplary over-voltage protection device 41 is fabricated using a semiconductor substrate 40 comprising lightly doped p-type silicon. N-well 42 is formed in the substrate 40 from lightly doped n-type material. Also formed within substrate 40 is heavily doped N+ region 45. Formed within N-well 42 is heavily doped P+ region 46. In accordance with the structure shown in FIG. 4, protection against positive voltage transients is obtained when it is configured with connection of circuit pad to P+ region 46 and connection of N+ region to VSS (ground). Furthermore, heavily doped P+ region 43 may also be fabricated within substrate 40 on the side of N+ region 45 away from the N-well. P+ region 43, as can most clearly be seen in the layout illustration of FIG. 6, is coupled to VSS (ground) and provides a closed loop guard-ring about the remainder of the over-voltage protection device 41. Heavily doped P+ region 43 also provides for a resistive coupling between the npn base/pnp collector and vss.

The P+ region 46, N-well 42, P-substrate 40 and N+ region 45 cooperate to form a lateral SCR device with P+ region 46 anode and N+ region 45 cathode. The SCR formed thereby comprises a pair of complementary bipolar transistors as follows. A first transistor of pnp variety is made up of P+ region 46 (emitter), N-well 42 (base) and P-substrate 40 (collector). A second transistor of npn variety is made up of N+ region 45 (emitter), P-substrate 40 (base) and N-well 42 (collector). The interface between the lightly doped n-type N-well and the lightly doped P-substrate is referred to as the avalanche junction. In a lateral device as exemplified in FIGS. 4-7, 10 and 11 the various regions or layers are said to be laterally adjacent or disposed.

FIG. 6 is a layout diagram of one method of laying out over-voltage protection device 41. Pad (not shown) is connected through vias to P+ region 46. Doped regions of over-voltage protection device 41 may be advantageously formed in P-substrate 40 using masking and ion implantation techniques which are well known in the art. On the other hand, other doping techniques may be used, such as diffusion from a solid source. N-well 42 is formed at the same time the N-wells for P type field effect transistors are formed on the integrated circuit containing over-voltage protection device 41. N+ regions 45 are formed at the time N-channel source/drain formation is performed for forming N-channel transistors on the integrated circuit. P+ regions 46 and 43 are formed at the time the source/drain formation is conducted for P channel transistors for the other components of the integrated circuit. Therefore, the embodiment of FIG. 4 including the more specific layout of FIG. 6 is completely compatible with CMOS fabrication processes.

FIG. 7 is an alternate layout diagram of one method of laying out over-voltage protection device similar to that of FIG. 6 corresponding to FIG. 4. Here, all similar layout features described with respect to FIGS. 4 and 6 are given a primed designation in FIG. 7. Additionally, however, a heavily doped N+ region 44 is formed within N-well 42′ and provides for a resistive coupling between the pnp base/npn collector and pad. This heavily doped N+ region 44 may also be formed at the time N-channel source/drain formation is performed for forming N-channel transistors on the integrated circuit. This resistive coupling and the resistive coupling afforded by heavily doped P+ region 43 allows for reverse current conduction in the event of a negative transient, effectively shunting the reverse biased np emitter junctions of the bipolar transistors. Additionally, these resistive couplings also provide for a degree of reduction in device sensitivity particularly to low-energy discharge events.

To provide a low trigger voltage, and hence protection against low voltage transients coupled at the pad, certain modifications to the basic SCR structure described may be made alone or in combination. Low trigger voltage as used herein means voltage across the SCR (anode to cathode), the magnitude of which is less than the trigger voltage magnitude across a similarly configured unmodified SCR effective to cause conventional avalanche junction voltage breakdown across the SCR avalanche junction. One such modification is to the dimension d which comprises the lateral separation between the P+ region 46 and the P-substrate 40 generally at or through a side-wall area of the N-well. An alternate modification is to the dimension d2 which comprises the vertical separation between the P+ region 46 and the P-substrate 40 generally at or through the trough area of the N-well. An alternate way of describing the dimensions d or d2 is the effective N-well 46 base width or thickness between the P+ region 46 emitter and the P-substrate 40 collector of the SCR's pnp bipolar transistor. Yet another modification is to the dimension d1 which comprises the lateral separation between the N+ region 45 and the N-well 42. An alternate way of describing the dimension d1 is the effective P-substrate 40 base width or thickness between the N+ region 45 emitter and the N-well 42 collector of the SCR's npn bipolar transistor.

By controlling the dimensions d, d1 and d2 alone or in combination to effect the desired reach-through effect, an SCR having a lower trigger voltage is obtained. For example, control of the dimension d and/or d2 can provide the desired reach-through effect in the bipolar pnp transistor of the SCR. The doping concentrations of the base region is also a factor which influences the reach-through characteristics of the device. Similarly, control of the dimension d1 can provide the desired reach-through effect in the bipolar npn transistor of the SCR. The thickness and doping concentration of the base region therefore are two main parameters affecting the reach-through characteristics. Control of one or both of the base region thickness and the doping therefore can be used to set the trigger voltage of the device.

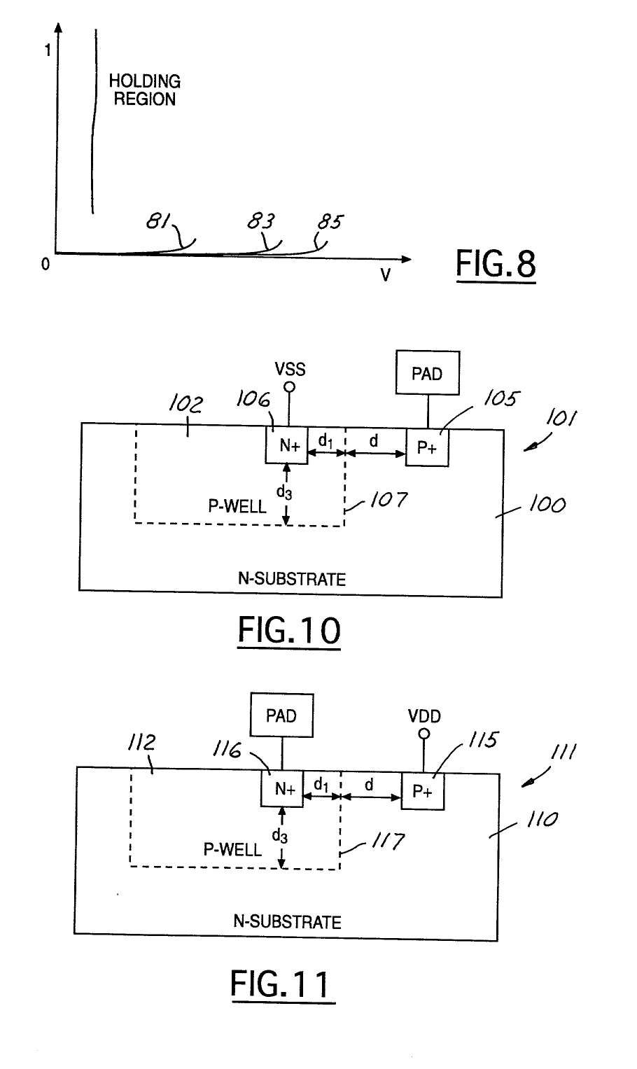

With further reference now to FIG. 8, a graph showing the current to voltage characteristic between the pad and VSS (ground) for exemplary over-voltage protection device 41 at three different base widths established in accordance with lateral layout base region widths d effecting a reach-through assisted conduction is illustrated. Each curve 81, 83 and 85 represents measured trigger voltage of reach-through assisted conduction SCRs wherein a lateral separation dimension d was fabricated at 0.15 mm, 0.25 mm and 0.35 mm, respectively. Conventional P-type dopant 1E14 to about 1B16 was used in these exemplary devices with concentrations of substantially less than 1E20 atoms/cm³ for heavily doped P+ regions and 1E18 to about 1E19 atoms/cm³ for lightly doped P-substrate. Conventional N-type dopant 1E14 to about 1E16 was used in these exemplary devices with concentrations of substantially less than 1E20 atoms/cm³ for heavily doped N+ regions and 1E18 to about 1E19 atoms/cm³ for lightly doped N-well. Curve 81 corresponds to a reach-through assisted trigger voltage of substantially 7.7 volts, curve 83 corresponds to a reach-through assisted trigger voltage of substantially 12.5 volts and curve 85 corresponds to a reach-through assisted trigger voltage of substantially 14.6 volts.

In one example comparison of a merged layout of a CMOS protection device according to an N-MOS assisted device, and a reach-through assisted device according to the invention including guard ring, the N-MOS device has an overall width of 120 mm and the reach-through assisted device has an overall width of 60 mm. With reference to FIG. 9, a human body model comparison of an N-MOS assisted device (curve 91) and a reach-through assisted device according to the invention (curve 95) is illustrated. As exhibited here, the N-MOS device reaches irreversible device burn-out maximum stress current (inflection point 93) at approximately 960 milliamps whereas the reach-through assisted device reaches irreversible device burn-out maximum stress current (inflection point 95) at approximately 2.55 amperes.

FIG. 5 illustrates an alternate embodiment of a SCR device in accordance with the present invention. The device of FIG. 5 is shown configured to pad and reference voltage VDD predominantly for negative transient (at pad) protection. The exemplary over-voltage protection device 51 is fabricated using a semiconductor substrate 50 comprising lightly doped p-type silicon. N-well 52 is formed in the substrate 50. Also formed within substrate 50 is heavily doped N+ region 55. Formed within N-well 52 is heavily doped P+ region 56. In accordance with the structure shown in FIG. 5, protection against negative voltage transients is obtained when it is configured with connection of circuit pad to N+ region 55 and connection of N+ region to VDD.

The P+ region 56, N-well 52, P-substrate 50 and N+ region 55 cooperate to form a lateral SCR device with P+ region 56 anode and N+ region 55 cathode. The SCR formed thereby comprises a pair of complementary bipolar transistors as follows. A first transistor of pnp variety is made up of P+ region 56 (emitter), N-well52 (base) and P-substrate 50 (collector). A second transistor of npn variety is made up of N+ region 55 (emitter), P-substrate 50 (base) and N-well 52 (collector). Dimensions d, d1 and d2 are also illustrated and correspond to the pnp transistor base thickness lateral), npn transistor base thickness and pnp transistor base thickness (vertical), respectively.

FIG. 10 illustrates an alternate embodiment of a SCR device in accordance with the present invention. The device of FIG. 10 is shown configured to pad and VSS (ground) predominantly for positive transient (at pad) protection. The exemplary over-voltage protection device 101 is fabricated using a semiconductor substrate 100 comprising lightly doped n-type silicon. P-well 102 is formed in the substrate 100. Also formed within substrate 100 is heavily doped P+ region 105. Formed within P-well 102 is heavily doped N+ region 106. In accordance with the structure shown in FIG. 10, protection against positive voltage transients is obtained when it is configured with connection of circuit pad to P+ region 105 and connection of N+ region to VSS.

The N+ region 106, P-well 102, N-substrate 100 and N+region 105 cooperate to form a lateral SCR device with P+ region 106 anode and P+ region 105 cathode. The SCR formed thereby comprises a pair of complementary bipolar transistors as follows. A first transistor of pnp variety is made up of P+ region 105 (emitter), N-substrate 100 (base) and P-well 102 (collector). A second transistor of npn variety is made up of N+ region 106 (emitter), P-well 102 (base) and N-substrate 100 collector) Dimensions d, d1 and d3 are also illustrated and correspond to the pnp transistor base thickness, npn transistor base thickness (lateral) and npn transistor base thickness (vertical), respectively.

FIG. 11 illustrates an alternate embodiment of a SCR device in accordance with the present invention. The device of FIG. 11 is shown configured to pad and VDD dominantly for negative transient (at pad) protection. The exemplary over-voltage protection device 111 is fabricated using a semiconductor substrate 110 comprising lightly doped n-type silicon. P-well 102 is formed in the substrate 110. Also formed within substrate 110 is heavily doped P+ region 115. Formed within P-well 112 is heavily doped N+ region 116. In accordance with the structure shown in FIG. 11, protection against negative voltage transients is obtained when it is configured with connection of circuit pad to N+ region 106 and connection of P+ region to VDD.

The N+ region 116, P-well 112, N-substrate 110 and N+region 115 cooperate to form a lateral SCR device with P+ region 115 anode and N+ region 116 cathode. The SCR formed thereby comprises a pair of complementary bipolar transistors as follows. A first transistor of pnp variety is made up of P+ region 115 (emitter), N-substrate 110 (base) and P-well 112 (collector). A second transistor of npn variety is made up of N+ region 116 (emitter), P-well 112 (base) and N-substrate 110 collector). Dimensions d, d1 and d3 are also illustrated and correspond to the pnp transistor base thickness, npn transistor base thickness (lateral) and npn transistor base thickness (vertical), respectively.

Alternative P-type dopants which may be utilized in the present invention include B/BF₂. Alternative N-type dopants which may be utilized in the present invention include P/AS. Heavily doped p-type regions or layers may be satisfactorily doped within the range of substantially 1E20 atoms/cm³ to 1E22 atoms/cm³. Lightly doped p-type regions or layers may be satisfactorily doped within the range of substantially 1E20 atoms/cm³ to 1E22 atoms/cm³. Heavily doped n-type regions or layers may be satisfactorily doped within the range of substantially 1E19 atoms/cm³ to 1E21 atoms/cm³. Lightly doped n-type regions or layers may be satisfactorily doped within the range of substantially 1E18 atoms/cm³ to 1E19 atoms/cm³. Base widths may satisfactorily be within the range of substantially 0.0005 mm to 0.05 mm.

An SCR made from layered fabrication techniques is specifically illustrated in FIG. 12. FIG. 12 is also useful as an alternative schematic for an SCR in general. Here, a heavily doped n-type region or layer N+ is adjacent a lightly doped p-type region or layer P−. The lightly doped p-type region or layer P− is adjacent a lightly doped n-type region or layer − and intermediate the N+ region or layer and the − region or layer. The lightly doped n-type region or layer − is adjacent a lightly doped p-type region or layer P+ and intermediate the P− region or layer and the P+ region or layer. The P+, − and P− regions or layers make up the pnp transistor of the SCR and comprise the emitter, base and collector thereof, respectively. The N+, P− and − regions or layers make up the npn transistor of the SCR and comprise the emitter, base and collector thereof, respectively. The SCR avalanche junction is at the interface between the − and P+ regions or layers and is labeled by the numeral 127 in FIG. 12. In a layered device as exemplified in FIG. 12 the various regions or layers are said to be vertically adjacent or disposed.

The invention has been described with respect to certain preferred embodiments intended to be taken by way of example and not by way of limitation. Certain alternative implementations and modifications may be apparent to one exercising ordinary skill in the art. Therefore, the scope of invention as disclosed herein is to be limited only with respect to the appended claims.

The embodiments of the invention in which an exclusive property or privilege is claimed are defined as follows.

What is claimed is:

1. An SCR voltage transient protection device comprising a pair of complementary bipolar transistors each having a respective base, emitter and collector, said SCR fabricated such that a reach-through effect across the base of at least one of the complementary bipolar transistors causes triggering of the device.

2. The device as claimed in claim 1 comprising a lateral SCR.

3. The device as claimed in claim 1 comprising a layered SCR.

4. The device as claimed in claim 1 wherein the reach-through effect occurs across the base of the one of the pair of complementary bipolar transistors that is of a pnp type.

5. The device as claimed in claim 1 wherein the reach-through effect occurs across the base of the one of the pair of complementary bipolar transistors that is of a npn type.

6. The device as claimed in claim 1 fabricated using a CMOS compatible process.

7. A silicon controlled rectifier device comprising:
a first lightly doped region having a first conductivity type formed in a second lightly doped region having a second conductivity type;
a first heavily doped region having said first conductivity type formed in said second lightly doped region;
a second heavily doped region having said second conductivity type formed in said first lightly doped region;
said second heavily doped region, said first lightly doped region and said second lightly doped region forming an emitter, a base and a collector, respectively, of a first transistor;
said first heavily doped region, said second lightly doped region and said first lightly doped region forming an emitter, a base and a collector, respectively, of a second transistor;
an avalanche junction formed at the interface of the first and second lightly doped regions having an avalanche junction breakdown voltage; and
wherein one of the first and second transistors is characterized by attaining a reach-through voltage prior to the avalanche junction attaining the avalanche junction breakdown voltage.

8. A silicon controlled rectifier device as claimed in claim 7 comprising a lateral device.

9. A silicon controlled rectifier device as claimed in claim 7 comprising a layered device.

10. The device as claimed in claim 7 wherein the one of the first and second transistors that attains its reach-through voltage prior to the avalanche junction attaining the avalanche junction breakdown voltage comprises the first transistor.

11. The device as claimed in claim 10 wherein the first transistor comprises a pnp type transistor.

12. The device as claimed in claim 10 wherein the first transistor comprises a npn type transistor.

13. The device as claimed in claim 7 wherein the one of the first and second transistors that attains its reach-through voltage prior to the avalanche junction attaining the avalanche junction breakdown voltage comprises the second transistor.

14. The device as claimed in claim 13 wherein the second transistor comprises a pnp type transistor.

15. The device as claimed in claim 13 wherein the second transistor comprises a npn type transistor.

16. The device as claimed in claim 8 wherein the one of the first and second transistors that attains its reach-through voltage prior to the avalanche junction attaining the avalanche junction breakdown voltage comprises the first transistor.

17. The device as claimed in claim 16 wherein the first transistor comprises a pnp type transistor.

18. The device as claimed in claim 16 wherein the first transistor comprises a npn type transistor.

19. The device as claimed in claim 17 wherein the base of the first transistor is substantially within the range of 0.0005 mm to 0.05 mm.

20. The device as claimed in claim 18 wherein the base of the first transistor is substantially within the range of 0.0005 mm to 0.05 mm.

21. The device as claimed in claim 8 wherein the one of the first and second transistors that attains its reach-through voltage prior to the avalanche junction attaining the avalanche junction breakdown voltage comprises the second transistor.

22. The device as claimed in claim 21 wherein the second transistor comprises a pnp type transistor.

23. The device as claimed in claim 21 wherein the second transistor comprises a npn type transistor.

24. The device as claimed in claim 22 wherein the base of the second transistor is substantially within the range of 0.0005 mm to 0.05 mm.

25. The device as claimed in claim 23 wherein the base of the second transistor is substantially within the range of 0.0005 mm to 0.05 mm.

26. A silicon controlled rectifier device comprising:
a lightly doped region of a first conductivity type;
a lightly doped region of a second conductivity type adjacent said lightly doped region of said first conductivity type;
a heavily doped region of said first conductivity type adjacent said lightly doped region of said second conductivity type wherein at least an intermediate portion of said lightly doped region of said second conductivity type is between said heavily doped region of said first conductivity type and said lightly doped region of said first conductivity type;
a heavily doped region of said second conductivity type adjacent said lightly doped region of said first conductivity type wherein at least an intermediate portion of said lightly doped region of said first conductivity type is between said heavily doped region of said second conductivity type and said lightly doped region of said second conductivity type;
an avalanche junction formed at the interface of the lightly doped regions; and
wherein a reach-through effect across at least one of said intermediate portions of said lightly doped regions occurs prior to an avalanche junction breakdown across the avalanche junction when voltage is impressed across the heavily doped regions.

27. A silicon controlled rectifier device as claimed in claim 26 wherein the device is a lateral device.

28. A silicon controlled rectifier device as claimed in claim 26 wherein the device is a layered device.

29. The device as claimed in claim 26 wherein the at least one of said intermediate portions of said lightly doped regions comprises an n-type material.

30. The device as claimed in claim 26 wherein the at least one of said intermediate portions of said lightly doped regions comprises an p-type material.

31. The device as claimed in claim 27 wherein said lightly doped region of said first conductivity type comprises a p-type material substrate, said lightly doped region of said second conductivity type comprises an n-type material well disposed in said p-type material substrate, said heavily doped region of said first conductivity type comprises a p-type material region disposed in said n-type material well, and said heavily doped region of said second conductivity type comprises an n-type material region disposed in said p-type material substrate.

32. The device as claimed in claim 27 wherein said lightly doped region of said first conductivity type comprises an n-type material substrate, said lightly doped region of said second conductivity type comprises a p-type material well disposed in said n-type material substrate, said heavily doped region of said first conductivity type comprises an n-type material region disposed in said p-type material well, and said heavily doped region of said second conductivity type comprises a p-type material region disposed in said n-type material substrate.

33. The device as claimed in claim 31 wherein the reach-through effect across said at least one of said intermediate portions occurs across said lightly doped n-type material well.

34. The device as claimed in claim 33 wherein the reach-through effect occurs through a portion of said lightly doped n-type material well that is laterally oriented with respect to said p-type material region.

35. The device as claimed in claim 33 wherein the reach-through effect occurs through a portion of said lightly doped n-type material well that is vertically oriented with respect to said p-type material region.

36. The device as claimed in claim 31 wherein the reach-through effect across said at least one of said intermediate portions occurs across said lightly doped p-type material substrate.

37. The device as claimed in claim 32 wherein the reach-through effect across said at least one of said intermediate portions occurs across said lightly doped p-type material well.

38. The device as claimed in claim 36 wherein the reach-through effect occurs through a portion of said lightly doped p-type material well that is laterally oriented with respect to said n-type material region.

39. The device as claimed in claim 36 wherein the reach-through effect occurs through a portion of said lightly doped p-type material well that is vertically oriented with respect to said n-type material region.
